(19) United States
(12) Patent Application Publication
(10) Pub. No.: US 2002/0194565 A1
(43) Pub. Date: Dec. 19, 2002

(54) Simultaneous built-in self-testing of multiple identical blocks of integrated circuitry

(76) Inventor: Karim Arabi, Burnaby (CA)

Correspondence Address: Oyen Wiggs Green & Mutala, The Station - Suite 480, 601 West Cordova Street, Vancouver, BC, V6B 1G1, CA

(21) Appl. No.: 09/882,052

(22) Filed: Jun. 18, 2001

(51) Int. Cl. G01R 31/28

(52) U.S. Cl. 714/729

(57) ABSTRACT

n identical integrated circuit blocks are simultaneously tested for defects. Each block contains m scan chains. The i^{th} scan chains in each block are identical (i=1, 2, . . . , m). During an i^{th} clock cycle, an i^{th} test vector is simultaneously applied to each block's i^{th} scan chain. The resultant n output signals are compared. If all n outputs are equal the i^{th} scan chain is designated defect-free for all n blocks; otherwise, the i^{th} scan chain is designated defective for one or more blocks. After sequentially repeating the test vector application, output comparison and designation process for i=1, 2, . . . , m the n blocks are designated defect-free if all m scan chains have been designated defect-free for all n blocks; otherwise, if one or more scan chains have been designated defective for one or more blocks, the n blocks are designated defective.

### TECHNICAL FIELD

This invention provides a technique for simultaneous built-in self-testing of multiple blocks of identical circuitry on an integrated circuit chip.

### BACKGROUND

Production testing of integrated circuit devices to verify their correct operation is becoming a complex problem, due to the increasing number of logic gates which must be tested on each device. The number of test pattern vectors which must be applied to a modern multi-million gate device in order to screen out defective devices can exceed the capability of currently available external automatic test equipment (ATE). Unacceptably long duration, expensive testing time is consumed in applying the required large number of test vectors to such devices, thereby decreasing production capacity and adversely affecting the time required to bring such devices to market.

One prior art approach to the problem has been to fabricate built-in self-test (BIST) circuitry on each device. Such circuitry can be dedicated to specific blocks of circuitry and actuated to test all blocks simultaneously with little or no intervention by ATE. However, BIST circuitry can be difficult to implement without violating the design rules applicable to the device itself and in a manner that achieves the required test coverage, and may adversely affect the time required to bring such devices to market. Another disadvantage is that prior art BIST circuitry can consume significant integrated circuit silicon area, thereby increasing manufacturing costs and decreasing manufacturing yields.

Integrated circuits commonly contain multiple blocks of identical circuitry. Examples include multi-link or multiple channel communication and networking devices in which the same communications link is replicated inside the device to achieve better integration. This invention provides a BIST technique which facilitates rapid, efficient simultaneous testing of such multiple identical blocks. The technique produces a signature which remains constant, irrespective of the circuit under test. The technique can be used either in conjunction with ATE or on a stand-alone basis to test multiple blocks of identical circuitry on the same integrated circuit chip. The testing time and the number of test patterns required to test multiple blocks is only marginally higher than is required to test a single block.

### SUMMARY OF INVENTION

The invention provides a method of testing for defects in n identical blocks of circuitry on an integrated circuit device. Each block contains m logic gate scan chains. The i^{th} scan chains in each block are identical, where i=1, 2, . . . , m (i.e. the 1^{st} scan chain in block 1 is identical to the 1^{st} scan chain in each of blocks 2, . . . , n; the 2^{nd} scan chain in block 1 is identical to the 2^{nd} scan chain in each of blocks 2, . . . , n; etc.). During an i^{th} clock cycle, an i^{th} test vector is simultaneously applied to each block's i^{th} scan chain, and the n output signals produced by those scan chains are simultaneously compared to one another. If all n output signals are equal to one another then the i^{th} scan chain is designated defect-free for all n blocks; otherwise, the i^{th} scan chain is designated defective for one or more of the n blocks. After sequential repetition of the above-described test vector application, output comparison and designation process for each value of i=1, 2, . . . , m the n identical blocks of circuitry are designated defect-free if all m scan chains have been designated defect-free for all of the n blocks; otherwise, if one or more scan chains have been designated defective for one or more of the n blocks, then the n identical blocks of circuitry are designated defective.

The invention also provides an apparatus for testing for defects in n identical blocks of circuitry on an integrated circuit device. Each block again contains m logic gate scan chains. The i^{th} scan chains in each block are identical, where i=1, 2, . . . , m. A test vector generator is connected to the input of each i^{th} scan chain in each block to simultaneously apply an i^{th} test vector to each i^{th} scan chain in each block during an i^{th} clock cycle. A comparator is connected to the output of each i^{th} scan chain in each block to simultaneously compare the n output signals produced by those scan chains during the i^{th} clock cycle. The comparator produces a “pass” output signal designating the i^{th} scan chain defect-free for all n blocks if all n output signals are equal to one another, or produces a “fail” output signal designating the i^{th} scan chain defective for one or more of the n blocks if all n output signals are not equal to one another. The test vector generator may be configured to produce m test vector outputs, with each i^{th} test vector output connected to an input of each i^{th} scan chain in each block. The comparator can be configured as m n-input sub-comparators, with each i^{th} sub-comparator having a j^{th} input connected to an output of a j^{th} one of the i^{th} scan chains in each block, where j=1, 2, . . . , n.

Each sub-comparator includes an n-input NOR gate with each j^{th} NOR gate input connected to the output of a j^{th} one of the i^{th} scan chains in each block; an n-input AND gate with each j^{th} AND gate input connected to the output of a j^{th} one of the i^{th} scan chains in each block; and, a 2-input OR gate having a first input connected to the NOR gate's output and a second output connected to the AND gate's output. Each sub-comparator can further include first and second D-type flip-flops, with the first flip-flop's D input connected to the OR gate's output and the second flip-flop's D input connected to the first flip-flop's Q output; a 2-input exclusive-OR gate having a first input connected to the first flip-flop's Q output and a second input connected the second flipflop's Q output; and, a 2-input multiplexor having a first input connected to the OR gate's output, a second input connected to the exclusive-OR gate's output, and an output selectably connectible to either one of the 2-input multiplexor's first or second inputs.

An m-input AND gate is provided, with each i^{th} AND gate input connected to an output of an i^{th} one of the sub-comparators. The AND gate's output constitutes a single pass/fail indication for all of the i^{th} scan chains in each block simultaneously.

The test vector generator can be a linear feedback shift register having m D-type flip-flops, m reconfigurable connection lines and m−1 exclusive-OR (“XOR”) gates. Each j^{th} connection line has an input connected between a Q output of a j^{th} one of the flip-flops, where j=1, 2, . . . , m. Each k^{th} XOR gate has a first input connected to an output of a k^{th} one of the connection lines, and a second input connected to an output of a k+1^{th} one of the XOR gates, where k=1, 2, . . . , m−2. The m−1^{th} XOR gate's first and second inputs are respectively connected to the outputs of the m−1^{th} and m^{th} connection lines.

The linear feedback shift register may also have m 2-input multiplexors. Each j^{th} 2-input multiplexor (excepting the j=1 2-input multiplexor) has an output connected to the D input of the j^{th} flip-flop, a first input connected to the \overline{Q} output of the j^{th} flip-flop, and a second input connected to the Q output of the j−1^{th} flip-flop. The j=1 2-input multiplexor has an output connected to the D input of the j=1 2-input multiplexor, a first input connected to the \overline{Q} output of the j=1 2-input multiplexor, and a second input connected to an output of the k=1 XOR gate. The output of each 2-input multiplexor is selectably connectible to either one of that multiplexor's first or second inputs.

### BRIEF DESCRIPTION OF DRAWINGS

FIG. 1 is a block diagram schematically depicting n identical circuit blocks configured for testing in accordance with the invention.

FIG. 2 provides further details of the FIG. 1 block and comparator circuitry.

FIG. 3 is a logic circuit diagram of a linear feedback shift register (LFSR) for generating test and flush vectors in accordance with the invention.

FIG. 4 is a logic circuit diagram of a preferred sub-comparator.

### DESCRIPTION

Throughout the following description, specific details are set forth in order to provide a more thorough understanding of the invention. However, the invention may be practiced without these particulars. In other instances, well known elements have not been shown or described in detail to avoid unnecessarily obscuring the invention. Accordingly, the specification and drawings are to be regarded in an illustrative, rather than a restrictive, sense.

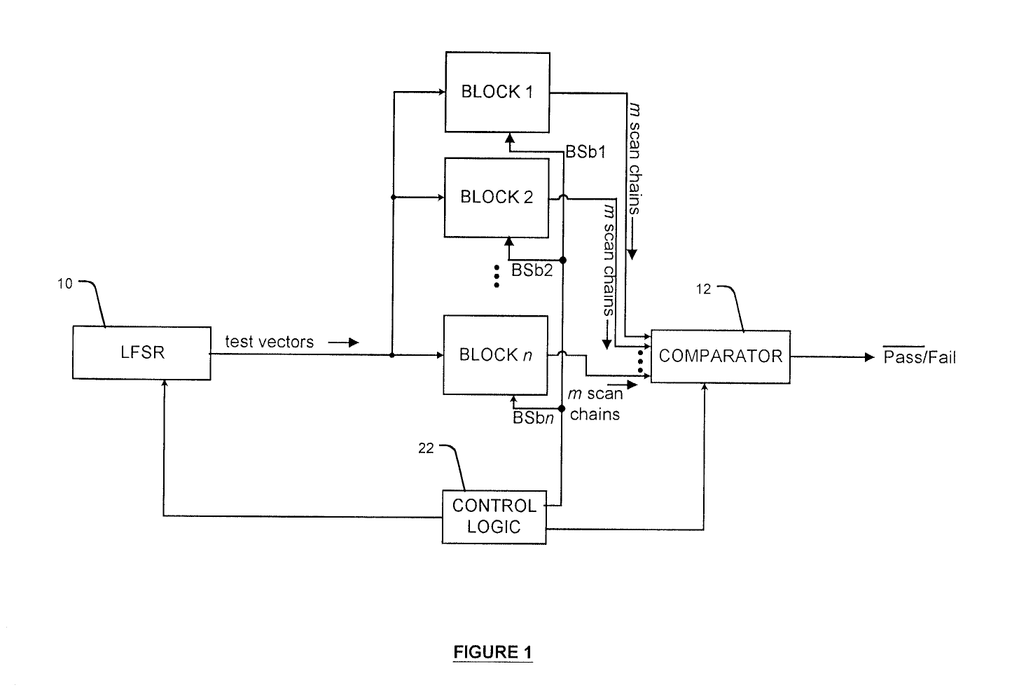

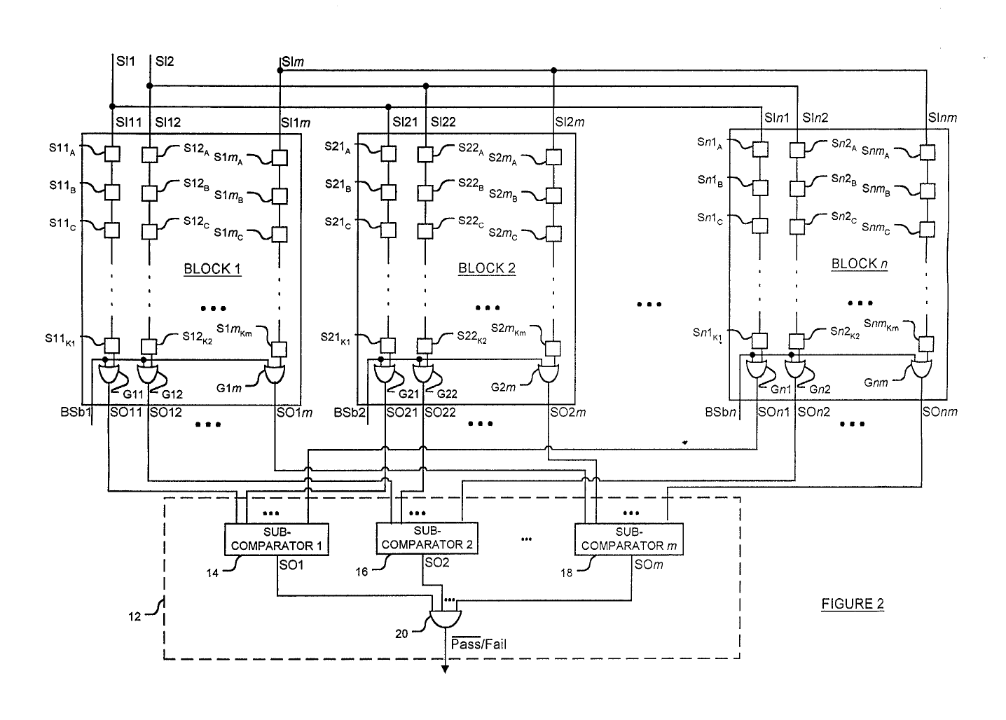

FIGS. 1 and 2 depict multiple identical blocks 1, 2, . . . , n of identical circuitry to be tested in accordance with the invention. Each one of blocks 1, 2, . . . , n is configured to contain multiple scan chains 1, 2, . . . , m of interconnected logic gates, such that the first scan chain in block 1 is identical to the first scan chain in each of blocks 2, . . . , n; the second scan chain in block 1 is identical to the second scan chain in each of blocks 2, . . . , n; and so on through to the m^{th} scan chain in block 1 which is identical to the m^{th} scan chain in each of blocks 2, . . . , n.

More particularly, as seen in FIG. 2, block 1 contains, between input SI11 and output SO11, a first scan chain comprising a plurality of series-connected logic gates S11_{A}, S11_{B}, S11_{C}, . . . ; block 2 contains, between input SI21 and output SO21, an identical first scan chain comprising a plurality of identical series-connected logic gates S21_{A}, S21_{B}, S21_{C}, . . . ; and, block n contains, between input SIn1 and output SOn1, another identical first scan chain comprising a plurality of series-connected logic gates Sn1_{A}, Sn1_{B}, Sn1_{C}, . . . . Similarly, block 1 contains, between input SI12 and output SO12, a second scan chain comprising a plurality of series-connected logic gates S12_{A}, S12_{B}, S12_{C}, . . . ; block 2 contains, between input SI22 and output SO22, an identical second scan chain comprising a plurality of identical series-connected logic gates S22_{A}, S22_{B}, S22_{C}, . . . ; and, block n contains, between input SIn2 and output SOn2, another identical second scan chain comprising a plurality of series-connected logic gates Sn2_{A}, Sn2_{B}, Sn2_{C}, . . . . The foregoing structure is repeated for each scan chain in each block, culminating in the final (m^{th}) scan chain, such that block 1 contains, between input SI1m and output SO1m, an m^{th} scan chain comprising a plurality of series-connected logic gates S1m_{A}, S1m_{B}, S1m_{C}, . . . ; block 2 contains, between input SI2m and output SO2m, an identical m^{th} scan chain comprising a plurality of identical series-connected logic gates S2m_{A}, S2m_{B}, S2m_{C}, . . . ; and, block n contains, between input SInm and output SOnm, another identical m^{th} scan chain comprising a plurality of series-connected logic gates Snm_{A}, Snm_{B}, Snm_{C}, . . . .

A single, on-chip, source of test vectors, such as linear feedback shift register (LFSR) 10 (FIG. 1) drives each block such that a first test vector is simultaneously applied to each one of the first scan chains in each one of blocks 1, 2, . . . , n; a second test vector is then simultaneously applied to each one of the second scan chains in each one of blocks 1, 2, . . . , n; and so on such that, finally, an m^{th} test vector is simultaneously applied to each one of the m^{th} scan chains in each one of blocks 1, 2, . . . , n. This is accomplished by tying the inputs SI11 , SI21, . . . , SIn1 of each one of the first scan chains together to provide a single input SI1 (FIG. 2) to which LFSR 10 applies the first test vector; tying the inputs SI12, SI22, . . . , SIn2 of each one of the second scan chains together to provide a single input SI2 to which LFSR 10 applies the second test vector; and so on culminating in tying together of the inputs SI1m, SI2m, . . . , SInm of each one of the m^{th} scan chains to provide a single input SIm to which LFSR 10 applies the m^{th} test vector.

The output signals produced by each one of blocks 1, 2, . . . , n are input to a comparator 12 as shown in FIG. 2. As seen in FIG. 2, comparator 12 consists of m identical n-input sub-comparators 14, 16, . . . , 18. The outputs SO11, SO21, . . . , SOn1 of each one of the first scan chains are respectively connected to the inputs of first sub-comparator 14, which simultaneously compares the output signals produced by each one of the first scan chains and produces a “pass” (i.e. logic “1”) output signal at first sub-comparator 14's output SO1 if the output signals produced by each one of the first scan chains are all identical to one another. Otherwise, if the output signals produced by each one of the first scan chains are not all identical to one another, a “fail” (i.e. logic “0”) output signal is produced at first sub-comparator 14's output SO1. The outputs SO12, SO22, . . . , SOn2 of each one of the second scan chains are respectively connected to the inputs of second sub-comparator 16, which simultaneously compares the output signals produced by each one of the second scan chains and produces a “pass” output signal at second sub-comparator 16's output SO2 if the output signals produced by each one of the second scan chains are all identical to one another. Otherwise, if the output signals produced by each one of the second scan chains are not all identical to one another, a “fail” output signal is produced at second sub-comparator 16's output SO2. The foregoing is repeated for each group of corresponding scan chains, culminating in connection of the outputs SO1m, SO2m, . . . , SOnm of each one of the m^{th} scan chains to the respective inputs of the m^{th} sub-comparator 18, which simultaneously compares the output signals produced by each one of the m^{th} scan chains and produces a “pass” output signal at m^{th} sub-comparator 18's output SOm if the output signals produced by each one of the m^{th} scan chains are all identical to one another. Otherwise, if the output signals produced by each one of the m^{th} scan chains are not all identical to one another, a “fail” output signal is produced at m^{th} sub-comparator 18's output SOm. Comparator 12 also includes an m-input AND gate 20. The outputs SO, SO2, . . . , SOm of each one the m sub-comparators 14, 16, . . . , 18 are respectively connected to the inputs of AND gate 20. Accordingly, if each one of the m sub-comparators produces a “pass” output signal then AND gate 20 also produces a “pass” output signal at its output; whereas, if any one or more of the m sub-comparators produces a “fail” output signal then AND gate 20 also produces a “fail” output signal at its output.

Since the first scan chains in each one of blocks 1, 2, . . . , n are assumed to be identical, the above-described simultaneous application of the first test vector to each of the first scan chains should result in simultaneous production of identical signals at the first scan chain outputs SO11, SO21, . . . , SOn1, which should in turn (i.e. in the absence of defects in the logic gates comprising each one of the first scan chains) result in production of a “pass” output signal by sub-comparator 14, thereby indicating an absence of defects in the logic gates comprising each one of the first scan chains. Similarly, since the second scan chains in each one of blocks 1, 2, . . . , n are assumed to be identical, the above-described simultaneous application of the second test vector to each of the second scan chains should (i.e. in the absence of defects in the logic gates comprising each one of the second scan chains) result in simultaneous production of identical signals at the second scan chain outputs SO12, SO22, . . . , SOn2, which should in turn result in production of a “pass” output signal by sub-comparator 16 thereby indicating an absence of defects in the logic gates comprising each one of the second scan chains; and so on throughout and including the m^{th} scan chains, such that production of a “pass” output signal by sub-comparator 18 indicates an absence of defects in the logic gates comprising each one of the m^{th} scan chains. Accordingly, production of a “pass” output signal by AND gate 20 is indicative of an absence of defects in the logic gates comprising all of blocks 1, 2, . . . , n. However, a defect in any one of the logic gates comprising any one of scan chains 1, 2, . . . , m which disrupts the defective gate's operation so as to result in production of a “fail” output signal by any one of the m sub-comparators will in turn result in production of a “fail” output signal by AND gate 20, thereby indicating the presence of a logic gate defect somewhere within one of blocks 1, 2, . . . , n.

As shown in FIG. 1, control logic 22 can be provided to selectively apply “block select” control signals BSb1, BSb2, . . . , BSbn to blocks 1, 2, . . . , n respectively in order to enable or disable selected blocks. This can be accomplished as shown in FIG. 2 by providing a first 2-input AND gate G11, G21, . . . , Gn1 at the output of each one of the respective first scan chains; providing a second 2-input AND gate G12, G22, . . . , Gn2 at the output of each one of the respective second scan chains; and so on, culminating in provision of an m^{th} 2-input AND gate G1m, G2m, . . . , Gnm at the output of each one of the respective m^{th} scan chains. The output of the final logic gate S11ₖ₁ in block 1's first scan chain is connected to one of the inputs of AND gate G11; and, the other input of AND gate G11 is connected to an output of control logic 22 at which control signal BSb1 is produced. The BSb1 output of control logic 22 is also connected to one of the inputs of each one of block 1's AND gates G12, . . . , G1m; with the other inputs of each one of AND gates G12, . . . , G1m being connected to the final logic gates S12ₖ₂, . . . , S1mₖₘ in each of block 1's second through m^{th} scan chains respectively. Similarly, in the case of block 2, the BSb2 output of control logic 22 is connected to one of the inputs of each one of block 2's AND gates G21, G22, . . . , G2m; with the other inputs of each one of AND gates G21, G22, . . . , G2m being connected to the final logic gates S21ₖ₁, S22ₖ₂, . . . , S2mₖₘ in each of block 2's first through m^{th} scan chains respectively. The foregoing is repeated for each block, culminating, in the case of block n, with the BSbn output of control logic 22 connected to one of the inputs of each one of block n's AND gates Gn1, Gn2, . . . , Gnm; with the other inputs of each one of AND gates Gn1, Gn2, . . . , Gnm being connected to the final logic gates Sn1ₖ₁, Sn2ₖ₂, . . . , Snmₖₘ in each of block n's first through m^{th} scan chains respectively. (The subscripts ₖ₁, ₖ₂, . . . , ₖₘ respectively correspond to the number of logic gates in each of the first through m^{th} scan chains.)

By applying a logic “1” BSb1 control signal to block 1, control logic 22 selectively enables all of block 1's first through m^{th} scan chains, such that the signals produced at block 1's outputs SO11, SO12, . . . , SO1m are respectively representative of the results of applying the first through m^{th} test vectors to block 1's inputs SI11, SI12, . . . , SI1m. Conversely, by applying a logic “0” BSb1 control signal to block 1, control logic 22 selectively disables all of block 1's first through m^{th} scan chains, masking the output signals produced at each one of block 1's outputs SO11, SO12, . . . , SO1m such that they have no effect on sub-comparators 14, 16, . . . , 18. Similarly, by applying a logic “1” BSb2 control signal to block 2, control logic 22 selectively enables all of block 2's first through m^{th} scan chains, such that the signals produced at block 2's outputs SO21, SO22, . . . , SO2m are respectively representative of the results of applying the first through m^{th} test vectors to block 2's inputs SI21, SI22, . . . , SI2m; or, by applying a logic “0” BSb2 control signal to block 2, control logic 22 selectively disables all of block 2's first through m^{th} scan chains, masking the output signals produced at each one of block 2's outputs SO21, SO22, . . . , SO2m such that they have no effect on sub-comparators 14, 16, . . . , 18. The same control capability is available for each one of blocks 1, 2, . . . , n such that by applying a logic “1” BSbn control signal to block n, control logic 22 selectively enables all of block n's first through m^{th} scan chains, such that the signals produced at block n's outputs SOn1, SOn2, . . . , SOnm are respectively representative of the results of applying the first through m^{th} test vectors to block n's inputs SIn1, SIn2, . . . , SInm; or, by applying a logic “0” BSbn control signal to block n, control logic 22 selectively disables all of block n's first through m^{th} scan chains, masking the output signals produced at each one of block n's outputs SOn1, SOn2, . . . , SOnm such that they have no effect on sub-comparators 14, 16, . . . , 18.

It is accordingly possible to individually test any selected one of blocks 1, 2, . . . , n by applying a logic “1” control signal to that one block in order to enable it, and by applying logic “0” control signals to all of the other blocks in order to disable them by masking their output signals such that they have no effect on sub-comparators 14, 16, . . . , 18, and by employing a predefined set of first through m^{th} test vectors such that the block being tested produces a predefined (hence recognizable) set of output signals in the absence of defects in that block. Alternatively, by simultaneously applying logic “1” BSb1, BSb2, . . . , BSbn control signals to each one of blocks 1, 2, . . . , n control logic 22 facilitates simultaneous testing of all of blocks 1, 2, . . . , n by passing through each scan chain's terminating AND gate to sub-comparators 14, 16, . . . , 18 the results of applying the first through m^{th} test vectors to the corresponding first through m^{th} scan chains in each of blocks 1, 2, . . . , n.

It is preferable to initially test comparator 12 and its connections to blocks 1, 2, . . . , n to verify correct operation thereof, before commencing testing of blocks 1, 2, . . . , n for defects. This is achieved by sequentially individually selecting each block (i.e. by applying a logic “1” control signal to each block in turn, while simultaneously applying logic “0” control signals to all of the other blocks, as explained above); and, while each block is selected, applying a predefined set of non-random bit pattern “flush” vectors to the input of each one of the selected block's first through m^{th} scan chains in order to test the integrity of each scan chain, including the connections between the logic gates comprising the respective scan chains (together with each scan chain's terminating 2-input AND gate), the connections between the scan chains' outputs and the sub-comparators' inputs, and the sub-comparators themselves. The preferred flush vector comprises an alternating pattern of logic “0's” and logic “1's” (i.e. 01010101 . . . ). Appropriate scan enable signals are applied to each scan chain while the flush vectors are input to the scan chains, to operate each scan chain in shift mode during the above-described initial comparator and connection test phase. When operating in shift mode, each scan chain passes the applied input signal through the scan chain's logic gates without alteration. Accordingly, in the absence of defects, and after k clock cycles, where k is the number of logic gates in the lengthiest scan chain in the block being tested (i.e. k is the largest integer in the set {ₖ₁, ₖ₂, . . . , ₖₘ}) the output signals produced by each scan chain in that block should be simultaneously identical to the input signal (i.e. 01010101 . . . ). Furthermore, if each scan chain successfully produces simultaneously identical output signals (i.e. 01010101 . . . ) after k clock cycles, and if comparator 12 (consisting of m sub-comparators 14, 16, . . . , 18 plus AND gate 20) is free of defects, then a “pass” signal is continuously produced at the output of AND gate 20, thereby confirming defect free operation of comparator 12, the scan chains and their respective interconnections as described above. Production of a “fail” signal at the output of AND gate 20 indicates the presence of at least one defect in comparator 12, the scan chains, or their respective interconnections as described above.

If the above-described initial comparator and connection test phase is successfully passed, then defect testing of blocks 1, 2, . . . , n can proceed. This is accomplished by simultaneously selecting all of blocks 1, 2, . . . , n (i.e. by causing control logic 22 to simultaneously apply logic “1 ” BSb1, BSb2, . . . , BSbn control signals to each of blocks 1, 2, . . . , n); and, simultaneously applying the first test vector to each one of the first scan chains in each block, simultaneously applying the second test vector to each one of the second scan chains in each block, and so on including simultaneously applying the m^{th} test vector to each one of the m^{th} scan chains in each block.

The test vectors are random patterns produced by LFSR 10, as hereinafter explained. Because a single (i.e. “first”) test vector is simultaneously applied to all of the first scan chains, and because the first scan chains are identical to one another, an absence of defects throughout all of the first scan chains results in simultaneous production of identical output signals at the SO11, SO21, . . . , SOn1 outputs of each of the first scan chains, thus continuously producing a “pass” signal at the SO1 output of sub-comparator 14, and thereby simultaneously confirming defect free operation of all of the first scan chains. Similarly, because a single (i.e. “second”) test vector is simultaneously applied to all of the second scan chains, and because the second scan chains are identical to one another, an absence of defects throughout all of the second scan chains results in simultaneous production of identical output signals at the SO12, SO22, . . . , SOn2 outputs of each of the second scan chains, thus continuously producing a “pass” signal at the SO2 output of sub-comparator 16, and thereby simultaneously confirming defect free operation of all of the second scan chains. Operation is the same for all remaining scan chains, throughout and including the m^{th} scan chain: because a single (i.e. “m^{th}”) test vector is simultaneously applied to all of the m^{th} scan chains, and because the m^{th} scan chains are identical to one another, an absence of defects throughout all of the m^{th} scan chains results in simultaneous production of identical output signals at the SOm, SO2m, . . . , SOnm outputs of each of the m^{th} scan chains, thus continuously producing a “pass” signal at the SOm output of sub-comparator 18, and thereby simultaneously confirming defect free operation of all of the m^{th} scan chains. An absence of defects throughout all of scan chains 1, 2, . . . , m in all of blocks 1, 2, . . . , n thus results in simultaneous input of m “pass” signals to AND gate 20, which in turn continuously produces a “pass” output signal, thereby simultaneously confirming defect free operation of all of blocks 1, 2, . . . , n.

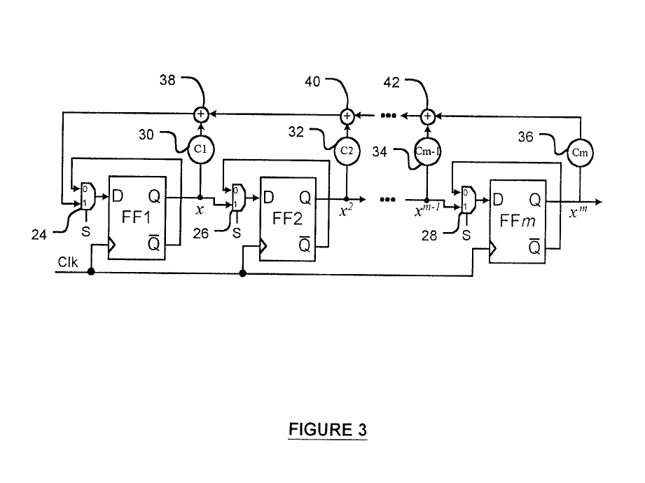

Construction and operation of LFSR 10 is now described with reference to FIG. 3. LFSR 10 incorporates a series of m flip-flops FF1, FF2, . . . , FFm where m is the number of scan chains in each of blocks 1, 2, . . . , n as previously explained. The outputs of m 2-input multiplexors are respectively connected to the flip-flops' D inputs (i.e. the output of first multiplexor 24 is connected to the D input of FF1, the output of second multiplexor 26 is connected to the D input of FF2, and so on culminating in connection of the output of m^{th} multiplexor 28 to the D input of FFm). FF1's Q output is connected to the “1” input of multiplexor 26; and, FF1's \overline{Q} output is fed back to the “0” input of FF1's input multiplexor 24. Application of a logic “0” signal to multiplexor 24's select (“S”) terminal causes multiplexor 24 to output the signal applied to multiplexor 24's “0” input; and, application of a logic “1” signal to multiplexor 24's select (“S”) terminal causes multiplexor 24 to output the signal applied to multiplexor 24's “1” input. FF2's Q output is connected to the “1” input of an input multiplexor (not shown) connected to the D input of a third flip-flop (not shown); and, FF2's \overline{Q} output is fed back to the “0” input of FF2's input multiplexor 26. Application of a logic “0” signal to multiplexor 26's select (“S”) terminal causes multiplexor 26 to output the signal applied to multiplexor 26's “0” input; and, application of a logic “1” signal to multiplexor 26's select (“S”) terminal causes multiplexor 26 to output the signal applied to multiplexor 26's “1” input. This structure is repeated, culminating with connection of the Q output of the m−1^{st} flip-flop (not shown) to the “1” input of FFm's input multiplexor 28 and with FFm's \overline{Q} output being fed back to the “0” input of FFm's input multiplexor 28. Application of a logic “0” signal to multiplexor 28's select (“S”) terminal causes multiplexor 28 to output the signal applied to multiplexor 28's “0” input; and, application of a logic “1” signal to multiplexor 28's select (“S”) terminal causes multiplexor 28 to output the signal applied to multiplexor 28's “1” input. A common clock signal “Clk” is applied to each of flip-flops FF1, FF2, . . . , FFm, as shown. Simultaneous application of logic “0” signals to the select terminals of all m multiplexors causes LFSR 10 to produce the aforementioned flush vector. Simultaneous application of logic “1” signals to the select terminals of all m multiplexors causes LFSR 10 to produce a random test vector.

The Q outputs of each of flip-flops FF1, FF2, . . . , FFm−1, FFm are tapped and fed back through a chain of reconfigurable connection lines 30, 32, . . . , 34, 36 and reconfigurable exclusive-OR (“XOR”) gates 38, 40, . . . , 42 to the “1” input of multiplexor 24. This can be accomplished in well known fashion by meamns of suitable computer programming. The connection line coefficients C1, C2, . . . , Cm have binary values (i.e. either “0” or “1”). If a particular connection line coefficient has the value “0” then the corresponding connection line does not exist, nor does the associated XOR gate exist. For example, if connection line 30's coefficient C1=0 then neither connection line 30 nor its associated XOR gate 38 exists. If a particular connection line coefficient has the value “1” then the corresponding connection line exists, as does the associated XOR gate. For example, if connection line 30's coefficient C1=1 then connection line 30 exists, as does XOR gate 38. To simplify matters, the following discussion assumes that all of the connection lines and XOR gates shown or implicit in FIG. 3 do in fact exist.

Consider the case in which logic “1” signals are applied to the select terminals of all m multiplexors to cause LFSR 10 to produce random test vectors. FFm's Q output is tapped and applied to reconfigurable connection line 36. The Q output of the m−1^{st} flip-flop (i.e. FFm−1 not shown) is tapped and applied to reconfigurable connection line 34. XOR gate 42 exclusive-ORs the outputs of FFm and FFm−1 and feeds the result back to to an immediately downstream (i.e. to the left, as viewed in FIG. 3) XOR gate (not shown) which exclusive-ORs XOR gate 42's output result with a component derived from an m−2^{nd} flip-flop (not shown). Ultimately, XOR gate 40 exclusive-ORs the immediately upstream (i.e. to the right, as viewed in FIG. 3) feedback result with a component derived from FF2; and, XOR gate 38 exclusive-ORs gate 40's output with a component derived from FF1.

Now consider the case in which logic “0” signals are applied to the select terminals of all m multiplexors to cause LFSR 10 to produce the aforementioned flush vector. Feedback of each flip-flop's \overline{Q} output to the “0” input of the same flip-flop's input multiplexor results in production at each flip-flop's Q output, during the next clock cycle, of the logic inverse of the signal at the flip-flop's \overline{Q} output. Thus, if FF1's \overline{Q} output is “1” during the current clock cycle then FF1's Q output is “0” during the current clock cycle, FF1's Q output is “1” and FF1's \overline{Q} output is “0” during the next clock cycle, etc. Accordingly, an alternating pattern of logic “0's” and logic “1's” (i.e. 01010101 . . . ) is produced at each flip-flop's Q output.

Overall, when configured to produce random test vectors, LFSR 10 generates a random pattern described by the polynomial:

P(x)=1+C₁x+C₂x²+ . . . +Cₘ₋₁x^{m-1}+Cₘx^{m}

For further details of the construction and operation of suitable LFSRs, see: Michael John and Sebastian Smith, “Application-Specific Integrated Circuits“, Addison Wesley Longman, Inc., 1997, pp. 771-773; or, Clive Maxfield, “The Ouroboros of the Digital Consciousness: Linear-Feedback-Shift Registers”, EDN Jan. 4, 1996, Cahners Business Information division of Reed Elsevier, Inc.

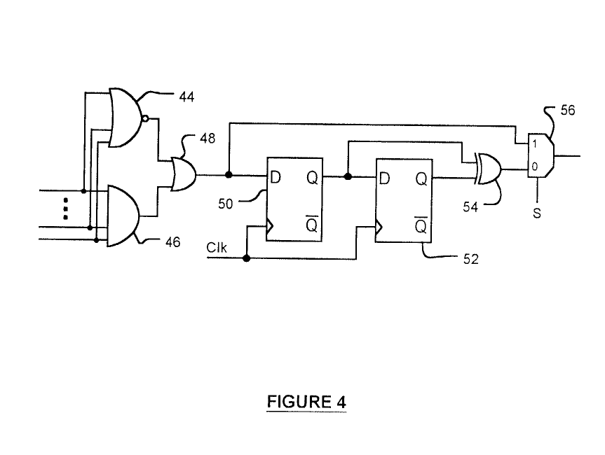

FIG. 4 depicts the preferred embodiment of each of sub-comparators 14, 16, . . . , 18. As previously explained, if n identical blocks are being tested, each sub-comparator receives, in parallel, n scan chain output signals from scan chain outputs SO1i, SO2i, . . . , SOni respectively, where i=1, 2, . . . , m indicates which one of the 1^{st}, 2^{nd} . . . , or m^{th} groups of scan chains is processed by the particular sub-comparator. The n scan chain output signals are input, in parallel, to n-input NOR gate 44 and to n-input AND gate 46. The outputs of NOR gate 44 and AND gate 46 are in turn connected to the respective inputs of 2-input OR gate 48. If the n scan chain output signals are simultaneously identical to one another, then OR gate 48 produces a logic “1” (i.e. “pass”) output signal; otherwise, OR gate 48 produces a logic “0” (i.e. “fail”) output signal. Operation in the defect testing mode is accomplished by applying a logic “1” signal to multiplexor 56's select (“S”) terminal, such that OR gate 48's output signal appears at the output of multiplexor 56 as the sub-comparator's output signal.

Operation in the initial comparator and connection test phase is accomplished by applying a logic “0” signal to multiplexor 56's select terminal, such that the sub-comparator's output signal reflects processing of OR gate 48's output signal through flip-flops 50, 52 and exclusive-OR (“XOR”) gate 54. More particularly, OR gate 48's output signal is applied to the D input of flip-flop 50. As previously explained, a flush vector alternating pattern of logic “0's” and logic “1's” (i.e. 01010101 . . . ) is input to the scan chains, which operate in shift mode to pass the flush vector without alteration such that, in the absence of scan chain defects, the output signals produced by each scan chain are simultaneously identical to the flush vector input signal (i.e. 01010101 . . . ). In the absence of scan chain defects, OR gate 48's output signal will also be identical to the flush vector input signal (i.e. 01010101 . . . ). The Q output of flip-flop 50 is connected to the D input of flip-flop 52 and to one of the inputs of XOR gate 54. The Q output of flip-flop 52 is connected to the other input of XOR gate 54. Consequently, if the flush vector input signal (i.e. 01010101 . . . ) is applied to the D input of flip-flop 50 (i.e. in the absence of scan chain defects) then XOR gate 54 continuously produces a logic “1” (i.e. “pass”) output signal, which appears at the output of multiplexor 56 as the sub-comparator's output signal.

It can thus be understood that the invention enables rapid, parallel testing of multiple blocks of identical circuitry on an integrated circuit chip. The required number of test vectors is reduced, by simultaneously applying a single 1^{st} test vector to each one of the first scan chains in each one of blocks 1, 2, . . . , n; then simultaneously applying a single 2^{nd} test vector to each one of the second scan chains in each one of blocks 1, 2, . . . , n; and so on, until a single m^{th} test vector is finally simultaneously applied to each one of the m^{th} scan chains in each one of blocks 1, 2, . . . , n. Thus, the invention requires no more test vectors than would be required to test a single block (plus the flush vector used to test the scan chains and comparator). More complex prior art techniques involving multiple-input shift registers, signature compaction, etc. are not required. A relatively simple linear feedback shift register (i.e. LFSR 10) serves as an on-chip pattern generator and is configurable to produce all of the test and flush vectors required for defect testing in accordance with the invention (i.e. LFSR 10 can produce either random test vectors, or a deterministic flush vector).

The invention does not require the circuit under test to produce a unique “signature” output for the circuit to “pass”; rather, continuous production of a logic “1” (i.e. “pass”) output by AND gate 20 simultaneously confirms defect free operation of all of blocks 1, 2, . . . , n. A further important advantage is the invention's ability to produce a pass/fail indication during each clock cycle. For example, if, during a 1^{st} clock cycle, a 1^{st} test vector is simultaneously applied to each one of the 1^{st} scan chains in each one of blocks 1, 2, . . . , n then AND gate 20 outputs either a logic “1” indicating defect free operation of all of those 1^{st} scan chains, or a logic “0” indicating defective operation of at least one of those 1^{st} scan chains; then, during a 2^{nd} clock cycle, a 2^{nd} test vector is simultaneously applied to each one of the 2^{nd} scan chains in each one of blocks 1, 2, . . . , n causing AND gate 20 to output either a logic “1” indicating defect free operation of all of those 2^{nd} scan chains, or a logic “0” indicating defective operation of at least one of those 2^{nd} scan chains; etc.

Further advantages of the invention include the ability to individually test any selected block for defects; the ability to pre-test the scan chains and comparator circuitry for defects; and, the fact that identical pass/fail test results are produced irrespective of whether the invention operates in defect testing mode or in the initial comparator and connection test mode.

As will be apparent to those skilled in the art in the light of the foregoing disclosure, many alterations and modifications are possible in the practice of this invention without departing from the spirit or scope thereof. For example, instead of using m discrete sub-comparators 14, 16, . . . , 18 as described above, one could alternatively use a comparator-multiplexor-detector structure. The comparator can be configured to compare the results from different blocks, with one multiplexor being used to bypass the comparator for operation in the initial comparator and connection test phase, and a second multiplexor being used for operation in defect testing mode to couple the scan chain output signals of a selected block to the comparator. A flush pattern detector (two flip-flops and an XOR gate) can be coupled to the second multiplexor's output detector. As another example, any one of a variety of prior art linear feedback shift register (LFSR) structures capable of producing flush and random test vectors as described herein can be used. Accordingly, the scope of the invention is to be construed in accordance with the substance defined by the following claims.

What is claimed is:

1. A method of testing for defects in n identical blocks of circuitry on an integrated circuit device, each one of said blocks containing m logic gate scan chains, each i^{th} one of said scan chains in each one of said blocks being identical, where i=1, 2, . . . , m, said method comprising:
(a) during an i^{th} clock cycle, simultaneously applying an i^{th} test vector to said i^{th} ones of said scan chains in each one of said blocks;
(b) during said i^{th} clock cycle, simultaneously comparing n output signals produced by said i^{th} ones of said scan chains in each one of said blocks;
(c) if said comparison reveals that all of said n output signals are equal, designating said i^{th} ones of said scan chains defect-free for all of said n blocks;
(d) if said comparison reveals that all of said n output signals are not equal, designating said i^{th} ones of said scan chains defective for one or more of said n blocks;
(e) sequentially repeating said applying, said comparing and said designating for each value of i=1, 2, . . . , m;
(f) if all in of said scan chains are designated defect-free for all of said n blocks, designating said n identical blocks of circuitry defect-free; and,
(g) if one or more of said scan chains are designated defective for one or more of said n blocks, designating said n identical blocks of circuitry defective.

2. A method as defined in claim 1, wherein said test vectors are random bit patterns.

3. A method as defined in claim 1, further comprising, during said i^{th} clock cycle, generating said i^{th} test vector as a random bit pattern.

4. A method as defined in claim 1, further comprising, during said i^{th} clock cycle, generating said i^{th} test vector as a pre-defined non-random bit pattern.

5. A method as defined in claim 4, wherein said pre-defined non-random bit pattern further comprises an alternating pattern of logic “0's” and logic “1's”.

6. A method as defined in claim 1, further comprising masking all but a selected one of said n output signals to thereby select for defect testing only that one of said blocks which produces said selected one of said n output signals.

7. Apparatus for testing for defects in n identical blocks of circuitry on an integrated circuit device, each one of said blocks containing m logic gate scan chains, each i^{th} one of said scan chains in each one of said blocks being identical, where i=1, 2, . . . , m, said apparatus comprising:
(a) a test vector generator connected to an input of said each i^{th} one of said scan chains in each one of said blocks to simultaneously apply an i^{th} test vector to said each i^{th} one of said scan chains in each one of said blocks during an i^{th} clock cycle;
(b) a comparator connected to an output of said each i^{th} one of said scan chains in each one of said blocks to simultaneously compare n output signals produced by said i^{th} ones of said scan chains in each one of said blocks during said i^{th} clock cycle, said comparator producing:
(i) a pass output signal designating said i^{th} ones of said scan chains defect-free for all of said n blocks if all of said n output signals are equal; and,
(ii) a fail output signal designating said i^{th} ones of said scan chains defective for one or more of said n blocks if all of said n output signals are not equal.

8. Apparatus as defined in claim 7, said test vector generator further comprising m test vector outputs, each i^{th} one of said test vector outputs connected to an input of said each i^{th} one of said scan chains in each one of said blocks.

9. Apparatus as defined in claim 7, said comparator further comprising m n-input sub-comparators, each i^{th} one of said sub-comparators having a j^{th} input connected to an output of a one of said j^{th} scan chains in each one of said blocks, where j=1, 2, . . . , n.

10. Apparatus as defined in claim 9, further comprising an m-input AND gate each i^{th} one of said AND gate inputs connected to an output of an i^{th} one of said sub-comparators.

11. Apparatus as defined in claim 7, said test vector generator further comprising a linear feedback shift register.

12. Apparatus as defined in claim 11, said linear feedback shift register further comprising m D-type flip-flops, m reconfigurable connection lines and m−1 reconfigurable exclusive-OR gates, each j^{th} one of said connection lines having an input connected to a Q output of a j^{th} one of said flip-flops, where j=1, 2, . . ., m, each k^{th} one of said exclusive-OR gates having a first input connected to an output of a k^{th} one of said connection lines and a second input connected to an output of a k+1^{th} one of said exclusive-OR gates, where k=1, 2, . . . , m−2, an m−1^{th} one of said exclusive-OR gates having a first input connected to an output of an m−1^{th} one of said connection lines and a second input connected to an output of an m^{th} one of said connection lines.

13. Apparatus as defined in claim 12, said linear feedback shift register further comprising m 2-input multiplexors, each j^{th} one of said 2-input multiplexors excepting a j=1 one of said 2-input multiplexors having:
(a) an output connected to a D input of a j^{th} one of said flip-flops;
(b) a first input connected to a \overline{Q} output of said j^{th} one of said flip-flops;
(c) a second input connected to a Q output of a j−1^{th} one of said flip-flops;
said j=1 one of said 2-input multiplexors having:
(d) an output connected to a D input of said j=1 one of said 2-input multiplexors;
(e) a first input connected to a \overline{Q} output of said j=1 one of said 2-input multiplexors; and,
(f) a second input connected to an output of a k=1 one of said exclusive-OR gates;
each one of said 2-input multiplexors having an output selectably connectible to either one of said first or said second inputs of said one of said 2-input multiplexors.

14. Apparatus as defined in claim 9, each one of said sub-comparators further comprising:
(a) an n-input NOR gate, each j^{th} one of said NOR gate inputs connected to an output of a j^{th} one of said i^{th} scan chains in each one of said blocks;
(b) an n-input AND gate, each j^{th} one of said AND gate inputs connected to an output of a j^{th} one of said i^{th} scan chains in each one of said blocks; and,
(c) a 2-input OR gate having a first input connected to an output of said NOR gate and a second output connected to an output of said AND gate.

15. Apparatus as defined in claim 14, each one of said sub-comparators further comprising:
(a) first and second D-type flip-flops, said first flip-flop having a D input connected to an output of said OR gate, said second flip-flop having a D input connected to a Q output of said first flip-flop;
(b) a 2-input exclusive-OR gate having a first input connected to a Q output of said first flip-flop and a second input connected to a Q output of said second flip-flop; and,
(c) a 2-input multiplexor having a first input connected to said output of said OR gate, a second input connected to an output of said exclusive-OR gate and an output selectably connectible to either one of said first or said second inputs of said 2-input multiplexor.

16. Apparatus as defined in claim 7, further comprising a controller for producing n block select signals, each j^{th} one of said block select signals coupled to a j^{th} one of said blocks, where j=1, 2, . . . , n, wherein all of said output signals produced by all of said scan chains in said j^{th} one of said blocks are masked if said j^{th} one of said block select signals has a first logic value and all of said output signals produced by all of said scan chains in said j^{th} one of said blocks are not masked if said j^{th} one of said block select signals has a second logic value opposite to said first logic value.

17. Apparatus as defined in claim 16, said controller further comprising, for each i^{th} one of said scan chains in each j^{th} one of said blocks, an ij^{th} 2-input AND gate having a first input connected to said output of said i^{th} one of said scan chains in said j^{th} one of said blocks, and having a second input connected to said j^{th} one of said block select signals.
